(19) United States
(12) Patent Application Publication
(10) Pub. No.: US 2026/0363059 A1
(43) Pub. Date: Nov. 12, 2026

(54) SEMICONDUCTOR DEVICE INCLUDING A CAPACITOR STRUCTURE AND MANUFACTURING METHOD THEREOF

(71) Applicant: TAIWAN SEMICONDUCTOR MANUFACTURING COMPANY, LTD., Hsinchu (TW)

(72) Inventors: Pin-Shun DING, Taichung (TW); Tzu-Ting LIU, Taoyuan (TW); Hsiang-Ku SHEN, Hsinchu (TW); Ying-Han CHIOU, Tainan (TW)

(21) Appl. No.: 19/203,246

(22) Filed: May 9, 2025

(51) Int. Cl. H10W 20/40

(52) U.S. Cl. CPC H10W 20/496

(57) ABSTRACT

In an embodiment, a semiconductor device is provided. The semiconductor device includes an interconnect structure disposed over a substrate; an insulating layer disposed over interconnect structure; a first conductive plate disposed over the insulating layer; a first passivation layer over the insulating layer and the first conductive plate; a plurality of trenches extending into the first passivation layer from an upper surface of the first passivation layer; and a capacitor structure including a first conductive layer, a second insulating layer, and a second conductive layer, wherein the first conductive layer, the second insulating layer, and the second conductive layer are disposed over the upper surface of the first passivation layer and extend into the trenches, wherein the first conductive layer is in contact with the first conductive plate.

### BACKGROUND

Electronic equipment involving semiconductor devices are essential for many modern applications. Technological advances in materials and design have produced generations of semiconductor devices where each generation has smaller and more complex circuits than the previous generation. In the course of advancement and innovation, functional density (i.e., the number of interconnected devices per chip area) has generally increased while geometric size (i.e., the smallest component that can be created using a fabrication process) has decreased. Such advances have increased the complexity of processing and manufacturing semiconductor devices.

Capacitors are commonly embedded in integrated passive devices and used in place of ceramic capacitors to reduce the size of mobile devices, reduce the cost of mobile devices, increase the functionality of mobile devices, or any combination of the foregoing. To provide improved characteristics and performance of the capacitors, metal-insulator-metal (MIM) capacitor designs comprising a plurality of metal layers and dielectric layers in an interleaved pattern have recently been introduced. When the layers of the MIM capacitors are formed within a recess having a high aspect ratio, the manufacturing processes become complicated and hard to control. Accordingly, an improved MIM capacitor structure and manufacturing methods thereof are desired.

### BRIEF DESCRIPTION OF THE DRAWINGS

Aspects of the present disclosure are best understood from the following detailed description when read with the accompanying Figures. It is noted that, in accordance with the standard practice in the industry, various features are not drawn to scale. In fact, the dimensions of the various features may be arbitrarily increased or reduced for clarity of discussion.

FIG. 1 is a perspective view of a semiconductor device including a device layer and an interconnect structure, in accordance with some embodiments.

FIG. 2 is a cross-sectional view of an interconnect structure of a semiconductor device, in accordance with some embodiments.

FIG. 3 illustrates a cross-sectional view of a semiconductor device including capacitor structure in a passivation structure, in accordance with some embodiments.

FIG. 4A-4D are schemes for illustrating a plan view of the arrangement of trenches for the trench-type capacitors, in accordance with some embodiments.

FIG. 4E is a scheme for illustrating a plan view of the arrangement of the first conductive layer and the second conductive layer in the capacitor structure as illustrated in FIG. 3, in accordance with some embodiments.

FIGS. 5-12 illustrate cross-sectional views of intermediate stages in the manufacturing of a semiconductor device, in accordance with some embodiments.

FIG. 13 illustrates a cross-sectional view of a semiconductor device including capacitor structure in a passivation structure, in accordance with some embodiments.

FIG. 14 illustrates a cross-sectional view of a semiconductor device including capacitor structure in a passivation structure, in accordance with some embodiments.

FIG. 15 is a scheme for illustrating a plan view of the arrangement of the first conductive layer and the third conductive layer in the capacitor structure as illustrated in FIG. 14, in accordance with some embodiments.

FIG. 16 illustrates a cross-sectional view of a semiconductor device including capacitor structure in a passivation structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples, wherein same reference numeral represents same elements. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature’s relationship to another element(s) or feature(s) as illustrated in the Figures. The spatially relative terms are intended to encompass different orientations of the device in use or operation in addition to the orientation depicted in the Figures. The apparatus may be otherwise oriented (rotated 90 degrees or at other orientations) and the spatially relative descriptors used herein may likewise be interpreted accordingly.

A semiconductor device including a capacitor structure is provided, in accordance with some embodiments. The capacitor structure includes trench-type capacitors. For example, the capacitor structure includes an insulating layer interposed a first conductive layer and a second conductive layer, and the insulating layer, the first conductive layer, and the second conductive layer are folded layers that extend into trenches to have an increased surface area. In some embodiments, the capacitor structure also includes a conductive plate connected to the first conductive layer and/or the second conductive layer. The conductive plate, along with the first or second conductive layer, work as an electrode of the capacitor structure. Because the conductive plate can provide a shorter electrical path than the first or second conductive layer, the conductive plate helps reduce sheet resistance of the electrode and enlarge filter bandwidth of the capacitor structure.

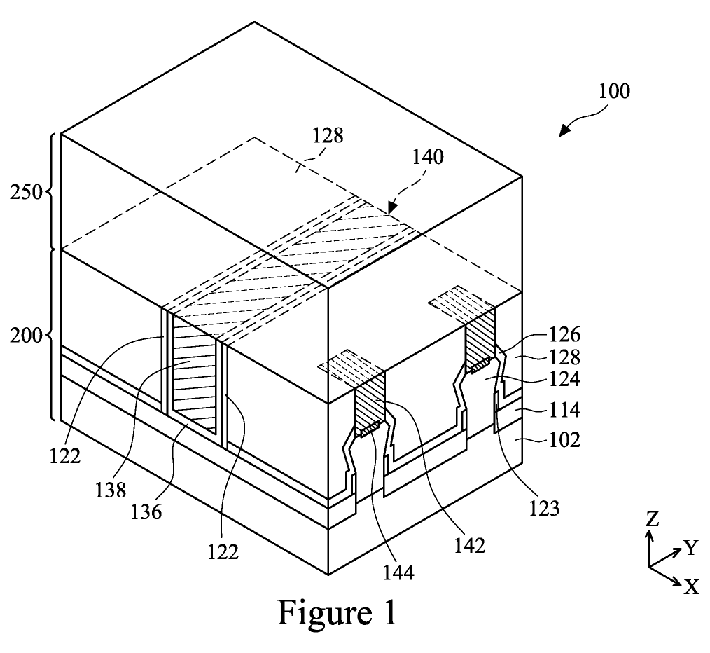

FIG. 1 is a perspective sectional view of a semiconductor device 100 including a device layer 200 and an interconnect structure 250. The device layer 200 includes a substrate 102 and one or more devices formed in or on the substrate 102. The substrate 102 may be a semiconductor substrate. In some embodiments, the substrate 102 includes a crystalline semiconductor layer on at least the surface of the substrate 102. The substrate 102 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb), and indium phosphide (InP). For example, the substrate 102 is made of Si. In some embodiments, the substrate 102 is a silicon-on-insulator (SOI) substrate, which includes an insulating layer (not shown) disposed between two silicon layers. In one aspect, the insulating layer is an oxygen-containing material, such as an oxide.

The substrate 102 may include various regions, including active regions and isolation regions. The active regions may be suitably doped with impurities (e.g., p-type or n-type impurities), for forming, for example, well regions.

As described above, the device layer 200 may include any suitable devices, such as transistors, diodes, imaging sensors, resistors, capacitors, inductors, memory cells, or a combination thereof. In some embodiments, the device layer 200 includes transistors, such as planar field effect transistors (FETs), FinFETs, nanostructure transistors, or other suitable transistors. The nanostructure transistors may include nanosheet transistors, gate-all-around (GAA) transistors, multi-bridge channel (MBC) transistors, or any transistors having the gate electrode surrounding the channels. An example of the device formed on the substrate 102 is a FinFET, which is shown in FIG. 1. The device layer 200 includes source/drain (S/D) regions 124 and gate stacks 140 (only one is shown in FIG. 1). Each gate stack 140 may be disposed between one or more S/D regions 124 serving as source regions and one or more S/D regions 124 serving as drain regions. For example, each gate stack 140 may extend along the Y-axis between one or more S/D regions 124 serving as source regions and one or more S/D regions 124 serving as drain regions. The S/D regions 124 may be closer to a frontside of the substrate 102 (e.g., a side connecting to the than interconnect structure 250) than a backside of the substrate 102. While not shown, channel regions are formed between the S/D regions 124 and have at least three surfaces wrapped around by the gate stack 140.

The S/D regions 124 may include a semiconductor material, such as Si or Ge, a III-V compound semiconductor, an II-VI compound semiconductor, or other suitable semiconductor material. Exemplary S/D region 124 may include, but are not limited to, Ge, SiGe, GaAs, AlGaAs, GaAsP, SiP, InAs, AlAs, InP, GaN, InGaAs, InAlAs, GaSb, AlP, GaP, and the like. Each of the S/D regions 124 comprises a plurality of layers containing same semiconductor material with different concentrations. The S/D regions 124 may include p-type dopants, such as boron; n-type dopants, such as phosphorus or arsenic; and/or other suitable dopants including combinations thereof. The S/D regions 124 may be formed by an epitaxial growth method using CVD, atomic layer deposition (ALD) or molecular beam epitaxy (MBE). The channel regions may include one or more semiconductor materials, such as Si, Ge, GeSn, SiGe, GaAs, InSb, GaP, GaSb, InAlAs, InGaAs, GaSbP, GaAsSb, GaN, or InP. The channel regions may include the same semiconductor material as the substrate 102. In some embodiments, the device layer 200 may include FinFETs, and the channel regions are a plurality of fins disposed below the gate stacks 140. In some embodiments, the device layer 200 may include nanostructure transistors, and the channel regions are surrounded by the gate stacks 140.

The gate stack 140 includes a gate electrode layer 138 disposed over the channel region (or surrounding the channel region for nanostructure transistors). The gate electrode layer 138 may be a metal-containing material such as tungsten, cobalt, aluminum, ruthenium, copper, multilayers thereof, or the like, and can be deposited by ALD, plasma enhanced chemical vapor deposition (PECVD), MBD, physical vapor deposition (PVD), or any suitable deposition technique. The gate stack 140 may further include a gate dielectric layer 136 disposed over the channel region. The gate electrode layer 138 may be disposed over the gate dielectric layer 136. In some embodiments, an interfacial layer (not shown) may be disposed between the channel region 108 and the gate dielectric layer 136, and one or more work function layers (not shown) may be formed between the gate dielectric layer 136 and the gate electrode layer 138. The interfacial dielectric layer may include a dielectric material, such as an oxygen-containing material or a nitrogen-containing material, or multilayers thereof, and may be formed by any suitable deposition method, such as CVD, PECVD, or ALD. The gate dielectric layer 136 may include a dielectric material such as an oxygen-containing material or a nitrogen-containing material, a high-k dielectric material having a k value greater than that of silicon dioxide, or multilayers thereof. The gate dielectric layer 136 may be formed by any suitable method, such as CVD, PECVD, or ALD. In some embodiments, the gate dielectric layer 136 may be a conformal layer. The term “conformal” may be used herein for ease of description upon a layer having substantial same thickness over various regions. The one or more work function layers may include aluminum titanium carbide, aluminum titanium oxide, aluminum titanium nitride, or the like.

Gate spacers 122 are formed along sidewalls of the gate stacks 140 (e.g., sidewalls of the gate dielectric layer 136). The gate spacers 122 may include silicon oxycarbide, silicon nitride, silicon oxynitride, silicon carbon nitride, the like, multi-layers thereof, or a combination thereof, and may be deposited by CVD, ALD, or other suitable deposition technique. In some embodiments, fin sidewall spacers 123 may be disposed on opposite sides of each S/D region 124, and the fin sidewall spacers 123 may include the same material as the gate spacers 122. Portions of the gate stacks 140, the gate spacers 122, and the fin sidewall spacers 123 may be disposed on isolation regions 114. The isolation regions 114 are disposed on the substrate 102. The isolation regions 114 may include an insulating material such as an oxygen-containing material, a nitrogen-containing material, or a combination thereof. In some embodiments, the isolation regions 114 are shallow trench isolation (STI). The insulating material may be formed by a high-density plasma chemical vapor deposition (HDP-CVD), a flowable chemical vapor deposition (FCVD), or other suitable deposition process. In one aspect, the isolation regions 114 includes silicon oxide that is formed by a FCVD process.

A contact etch stop layer (CESL) 126 is formed on the S/D regions 124 and the isolation region 114, and an interlayer dielectric (ILD) layer 128 is formed on the CESL 126. The CESL 126 can provide a mechanism to stop an etch process when forming openings in the ILD layer 128. The CESL 126 may be conformally deposited on surfaces of the S/D regions 124 and the isolation regions 114. The CESL 126 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be deposited by CVD, PECVD, ALD, or any suitable deposition technique. The ILD layer 128 may include an oxide formed by tetraethylorthosilicate (TEOS), un-doped silicate glass, or doped silicon oxide such as borophosphosilicate glass (BPSG), fused silica glass (FSG), phosphosilicate glass (PSG), boron doped silicon glass (BSG), organosilicate glass (OSG), SiOC, and/or any suitable low-k dielectric materials (e.g., a material having a dielectric constant lower than that of silicon dioxide), and may be deposited by spin-on, CVD, FCVD, PECVD, PVD, or any suitable deposition technique.

S/D contacts 142 may be disposed in the ILD layer 128 and over the S/D regions 124. The S/D contacts 142 may be electrically conductive and include a material having one or more of Ru, Mo, Co, Ni, W, Ti, Ta, Cu, Al, TiN or TaN, and the conductive contact may be formed by any suitable method, such as electro-chemical plating (ECP), CVD, or PVD. A silicide layer 144 may be disposed between the S/D contacts 142 and the S/D regions 124. The silicide layers 144 may be made of a metal or metal alloy silicide, and the metal includes a noble metal, a refractory metal, a rare earth metal, alloys thereof, or combinations thereof.

In integrated circuits, interconnection structures (or interconnect structures) are used to provide signal routing and power supply to semiconductor devices. An integrated circuit chip typically includes a device layer, fabricated during front-end-of-line (FEOL) and middle-end-of-line (MEOL) processes, and a back-end-of-line (BEOL) layer. The device layer may be formed in and/or on the substrate, and the BEOL layer is formed on a front side and/or backside of the device layer. The device layer may include various semiconductor devices, such as transistors, diodes, capacitors, resistors, etc., and may be formed in and/or on the substrate. In some embodiments, the device layer may also include the MEOL structures, such as one or more dielectric layers with conductive structures connected to gates and source/drain features in the device layer. Interconnection structures typically include conductive lines and vias formed in both the device layer and the BEOL layers.

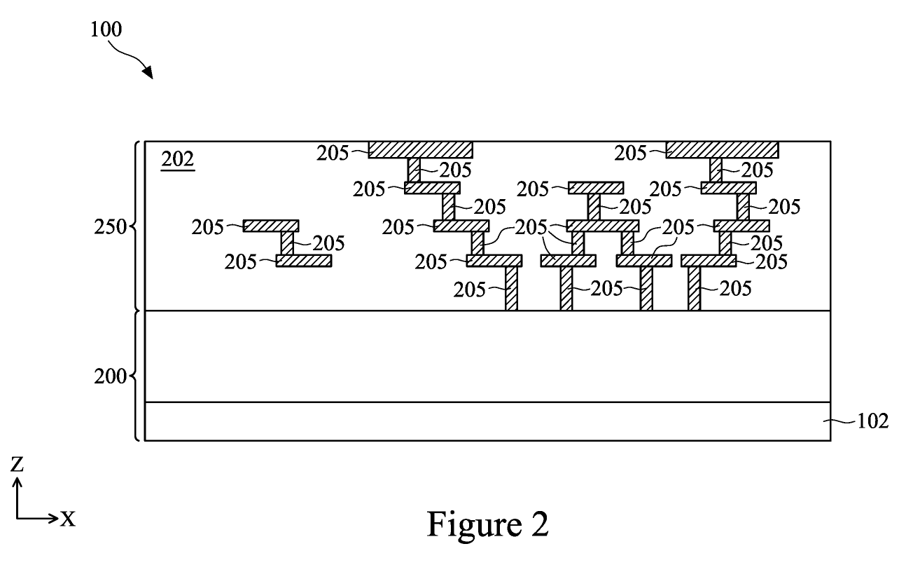

FIG. 2 is a cross-sectional view of an interconnect structure of an intermediate stage of manufacturing the semiconductor device 100 with a detailed structure depicting its interconnect structure, in accordance with some embodiments. The interconnect structure 250 is formed over the device layer 200. The interconnect structure 250 includes various conductive features 205, such as conductive lines, conductive pads, or conductive vi, formed in dielectric layers 202. The dielectric layers 202 may be an intermetal dielectric (IMD) layers or interlayer dielectric (ILD) layers. Multiple levels of conductive features 205 may be embedded in the dielectric layers 202. The conductive features 205 may include conductive pads, conductive lines, and conductive vias. The dielectric layer 202 includes a dielectric material, such as SiOₓ, SiOₓC_{y}H_{z}, or SiOₓC_{y}, where x, y and z are integers or non-integers. In some embodiments, the dielectric layers 202 includes a low-k dielectric material having a k value less than that of silicon oxide. The conductive features 205 may be made from one or more electrically conductive materials, such as metal, metal alloy, metal nitride, or silicide. The conductive features 205 are arranged in levels to provide electrical paths to the gate electrode layer 138 (FIG. 1) and S/D contacts 142 (FIG. 1) in the device layer.

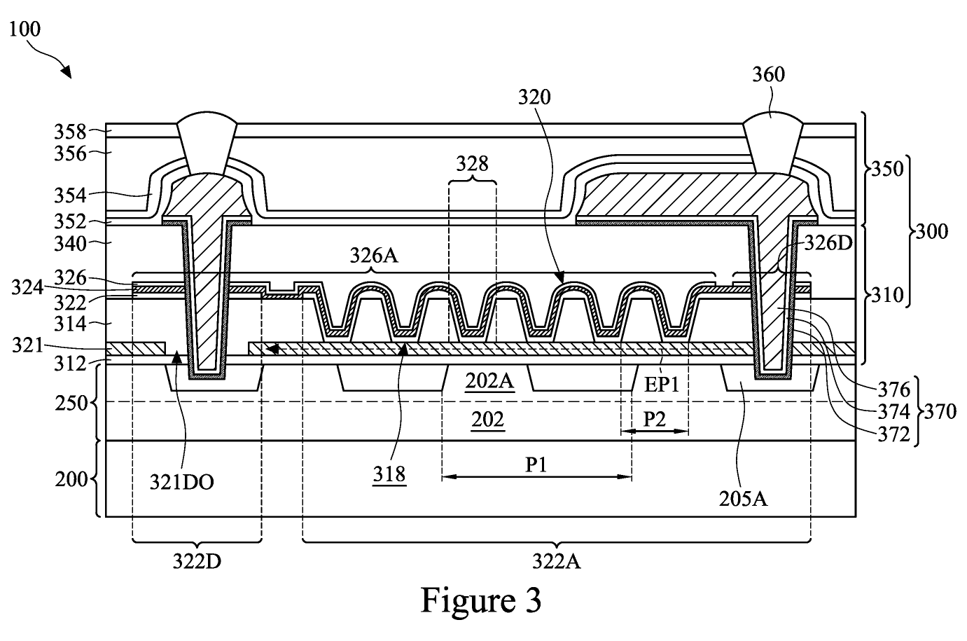

FIG. 3 is a cross-sectional view of an intermediate stage of manufacturing the semiconductor device 100 with a detailed structure depicting its passivation structure, in accordance with some embodiments. In FIG. 3, a first passivation structure 310 is formed over the interconnect structure 250. For the clarity purposes, only the top level 205A of the conductive features 205 is shown. The top level 205A of the conductive features 205 (referring to as conductive features 205A hereinafter) may include conductive lines and conductive pads embedded in a top layer of the dielectric layers 202A (referring to as top dielectric layer 202A hereinafter). In some embodiments, neighboring conductive features 205A may have a pitch P1 of about 1 µm to about 250 µm. The top dielectric layer 202A may be a low-k dielectric material or silicon oxide. The top dielectric layer 202A may have a thickness of about 300 nm to about 800 nm.

The semiconductor device 100 may include a first passivation structure 310 disposed over the interconnect structure 250 and a second passivation structure 350 disposed over the first passivation structure 310. A capacitor structure 320 and/or other passive devices may be formed in the first passivation structure 310. The capacitor structure 320 may include a first conductive plate 321 and a plurality of capacitor units 328 disposed over the first conductive plate 321. Bonding structures 360 may be formed in or surrounded by the second passivation structure 350. In some embodiments, conductive through vias 370 extend through the first passivation structure 310 to electrically couple the bonding structures 360 and the conductive features 205 of the interconnect structure 250.

In some embodiments, the first passivation structure 310 includes an etch stop layer 312 over the dielectric layer 202 of the interconnect structure 250 and a first passivation layer 314 over the etch stop layer 312. The etch stop layer 312 may be an insulating layer. The etch stop layer 312 may include a material different from the dielectric layer 202 to have different etch selectivity compared to the dielectric layer 202. In some embodiments, the etch stop layer 312 is made of an insulating material, such as a carbide, a nitride, a metal oxide, a metal nitride, or a combination thereof. Suitable materials for the etch stop layer 312 may include, but not limited to silicon carbide, silicon carbon nitride, silicon oxycarbonitride, aluminum nitride, aluminum oxide, titanium oxide, a combination thereof, or the like. The etch stop layer 312 may be formed by any suitable process, such as CVD, ALD, PVD, PECVD, a combination therefore, or the like. The etch stop layer 312 has a thickness from about 100 nm to about 200 nm, in accordance with some embodiments. The etch stop layer 312 may partially or completely resist the etch processes for forming openings used for containing the conductive through vias 370. As such, an additional etch process with lower etch rate can be implemented to etch through the etch stop layer 312 for extending the openings through the etch stop layer 312, thereby reducing or avoiding overetch that may damage the conductive features 205A of the interconnect structure 250.

The first passivation layer 314 includes a different material from the top dielectric layer 202A and the etch stop layer 312, in accordance with some embodiments. The first passivation layer 314 is a passivation layer that provides, for example, moisture seal properties or mechanical robustness, to protect the underlying interconnect structure 250 and device layer 200. The first passivation layer 314 may have a dielectric constant greater than that of the top dielectric layer 202A in the interconnect structure 250. In some embodiments, the first passivation layer 314 includes silicon nitride, silicon oxynitride, or a combination thereof. In an embodiment that the top dielectric layer 202A is silicon oxide, and the first passivation layer 314 is silicon nitride. In some embodiments, the first passivation layer 314 has a thickness greater than the thickness of the etch stop layer 312 and the thickness of the top dielectric layer 202A. For example, the first passivation layer 314 may have a thickness of about 400 nm to about 1000 nm.

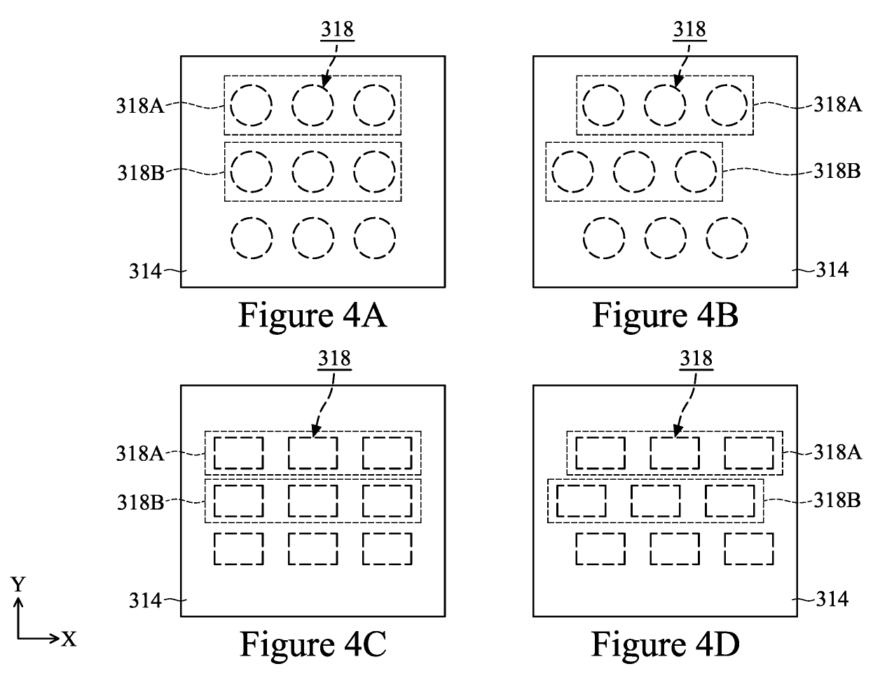

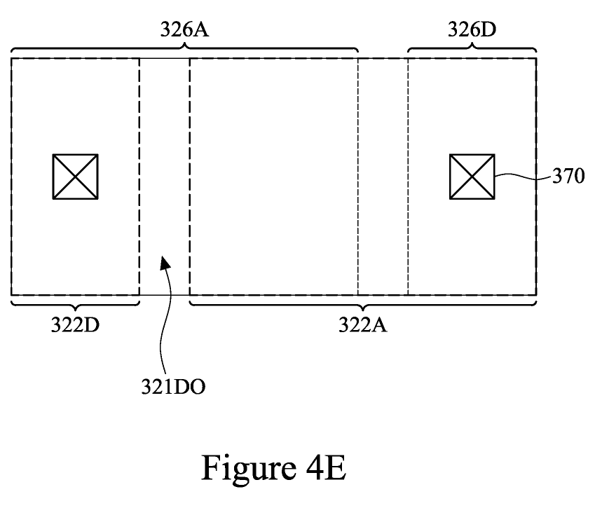

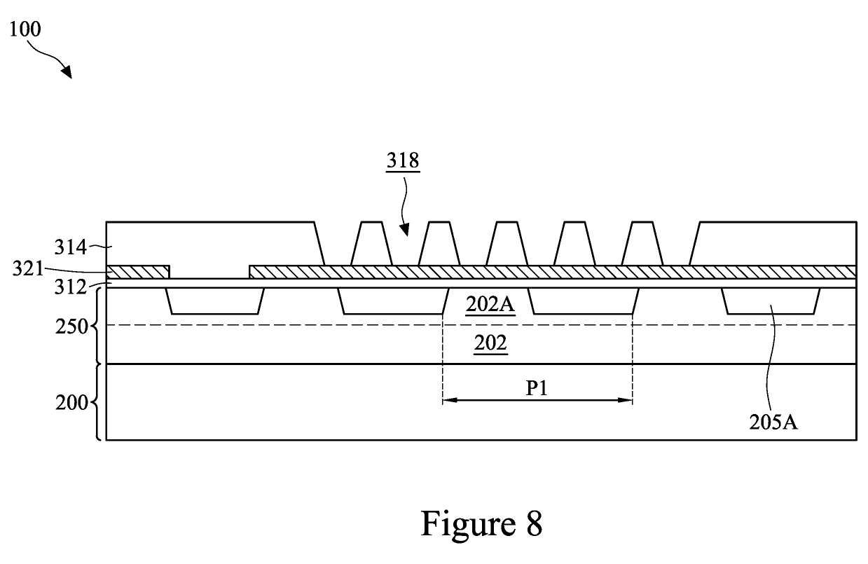

The first conductive plate 321 of the capacitor structure 320 may be disposed over the etch stop layer 312 and covered by the first passivation layer 314. The first conductive plate 321 may have a flat upper surface and a flat bottom surface. A plurality of trenches 318 (see also FIG. 8) are formed in the first passivation layer 314, in accordance with some embodiments. The trenches 318 may extend into the first passivation layer 314 from an upper surface of the first passivation layer 314. In an embodiment, the trenches 318 expose the upper surface of the first conductive plate 321. In some embodiments, the trenches 318 penetrate into or through the first conductive plate 321. The trenches 318 may substantially have a circular shape, an oval shape, a square shape, a rectangular shape, the like, or combinations thereof in the plan view. FIGS. 4A-4D show the arrangements of the trenches 318 in a plan view. In embodiments illustrated in FIGS. 4A and 4B, the trenches 318 have a circular shape although it can be other shapes such as a square shape. The trenches 318 may have a plurality of rows arranged along a first direction (e.g., X-direction), including a first row 318A and a second row 318B neighbored in a second direction perpendicular to the first direction (e.g., Y-direction). In an embodiment illustrated in FIG. 4A, the first row 318A and the second row 318B may be aligned in the first direction. In an embodiment illustrated in FIG. 4B, the first row 318A and the second row 318B are staggered. FIGS. 4C and 4D illustrate the trenches 318 each having a rectangular shape with aligned or staggered first row 318A and second row 318B, respectively, in accordance with some embodiments. In some embodiments, at least one of the trenches 318 has a width of about 2.5 µm to about 5 µm. The neighboring trenches 318 in the first direction may have a pitch P2 of about 200 nm to about 800 nm. In some embodiments, the trenches 318 have a height of about 300 to about 800 nm.

The capacitor structure 320 also includes include a first conductive layer 322, an insulating layer 324, and a second conductive layer 326, which form a metal-insulator-metal (MIM) structure. The first conductive layer 322 may extend over the upper surface of the first passivation layer 314 and into the trenches 318. The first conductive layer 322 may be in contact with the first conductive plate 321. The insulating layer 324 may be disposed over the first conductive layer 322, and the second conductive layer 326 may be disposed over the insulating layer 324. The insulating layer 324 and the second conductive layer 326 may extend over the upper surface of the first passivation layer 314 and into the trenches 318. In some embodiments, the first conductive layer 322, the insulating layer 324, and the second conductive layer 326 in the trenches 318 form the capacitor units 328 of the capacitor structure 320. The capacitor units 328 may contribute a major portion of the capacitor structure 320. Although not shown in Figures, in some embodiments, seams or air gaps are formed in the trenches 318, being sealed by second conductive layer 326 or the insulating layer 324.

In an embodiment, the first conductive layer 322 includes Al, W, Co, Ti, Ta, TiN, TaN, or an alloy thereof. In some embodiments, the thickness of the first conductive layer 322 is in a range from about 10 nm to about 100 nm, or in a range from about 20 nm to about 50 nm, depending on the design and/or process requirements. The insulating layer 324 is formed over the first conductive layer 322 and the first passivation layer 314. The first conductive plate 321 may be or include a conductive material that has a lower electrical resistivity than that of the first conductive layer 322. For example, the first conductive plate 321 may be Al or W when the first conductive layer 322 is TiN. In an embodiment that W is used for the first conductive plate 321, a glue layer such as Ti or TiN may be disposed between the first conductive plate 321 and the etch stop layer 312. In some embodiments, the first conductive plate 321 has a same material as the first conductive layer 322. The first conductive plate 321 may have a thickness greater than the thickness of the first conductive layer 322. For example, the first conductive plate 321 may have a thickness of about 20 nm to about 70 nm. The first conductive layer 322 and the first conductive plate 321 may collectively work as the bottom electrode of the capacitor structure 320. Because the first conductive plate 321 can provide a material with lower resistivity, a shorter electrical path (straight line EP1 of the first conductive plate 321 as compared to the folded electrical path of the first conductive layer 322), and/or a greater thickness than that of the first conductive layer 322, the capacitor structure 320 can have a reduced resistance and a wider filter bandwidth (e.g., about 75 MHz to about 575 MHz). Also, the capacitor structure 320 may have an increased charging and discharging speed because of the reduced electrical path.

In some embodiments, the insulating layer 324 includes one or more high-k dielectric layers having a dielectric constant greater than that of silicon oxide. In some embodiments, the insulating layer 324 includes one or more layers of a metal oxide or a silicate of Hf, Al, Zr, combinations thereof, and multi-layers thereof. In certain embodiments, hafnium oxide is used. Other suitable materials include La, Mg, Ba, Ti, Pb, Zr, in the form of metal oxides, metal alloy oxides, and combinations thereof. Exemplary materials include MgO, BaTiO, BaSrTiO, PbTiO, PbZrTiyO, AlO, LaO, TaO, YO, HfO, ZrO, HfSiON, YGeO, YSiO and LaAlO, a combination therefore, or the like. In some embodiments, the insulating layer 324 has a thickness in a range from about 1 nm to about 10 nm, and in a range from about 3 nm to about 8 nm in other embodiments, depending on design and/or process requirements. The second conductive layer 326 may include or be the same material as the first conductive layer 322.

In some embodiments, at least a portion of the first conductive layer 322 over the upper surface of the first passivation layer 314 (e.g., the portion between trenches 318) has a curved top surface. At least a portion of the insulating layer 324 over an upper surface of the first passivation layer 314 (e.g., the portion between trenches 318) may have a curved top surface. At least a portion of the second conductive layer 326 over the upper surface of the first passivation layer 314 (e.g., the portion between trenches 318) may have a curved top surface.

The first passivation structure 310 further includes a filling layer 340 over the capacitor structure 320, in accordance with some embodiment. The filling layer 340 may extend into and fill the remaining space of the trenches 318. The filling layer 340 may have a similar material as the first passivation layer 314. In an embodiment, the filling layer 340 has a planarized upper surface.

The conductive through vias 370 may extend through the filling layer 340 and the capacitor structure 320, such as extending through the second conductive layer 326, the insulating layer 324, and the first conductive layer 322. The conductive through vias 370 may also extend through the first passivation layer 314 and the etch stop layer 312 to be electrically coupled to the underlying conductive features 205A of the interconnect structure 250. The conductive through vias 370 may include a low-resistivity main conductive material 376, such as Cu, W, Ru, Al, Au, Ag, or a combination thereof. The conductive through vias 370 may also include a barrier layer 372 and/or a seed layer 374 between the main conductive material 376 and layers neighboring the conductive through vias 370. The barrier layer 372 may include a metal such as Ti, Ta, Ru, or a metal nitride such as TiN, TaN, or a combination thereof. The barrier layer 372 may have a thickness ranging from about 1 nm to about 10 nm. If the thickness of the barrier layer 372 is less than about 1 nm, the barrier layer 372 may not be sufficient to prevent diffusion of main conductive material 376. The seed layer 374 may include Cu, Ti, or a composite structure containing Cu and Ti layers.

In some embodiments, the first conductive layer 322 includes a first dummy region 322D for allowing one or more the conductive through vias 370 to pass through, and the second conductive layer 326 includes a second dummy region 326D for allowing one or more the conductive through vias 370 to pass through. The first dummy region 322D of the first conductive layer 322 may be electrically isolated from other portions of the first conductive layer 322 (e.g., portions for forming the capacitor units 328), and the second dummy region 326D of the second conductive layer 326 may be electrically isolated from other portions of the second conductive layer 326 (e.g., portions for forming the capacitor units 328). The first dummy region 322D may not overlap the second dummy region 326D in the plan view. In an embodiment, the first conductive plate 321 has a pattern corresponding to the first conductive layer 322. Alternatively, the first conductive plate 321 may have a first area corresponding to the first active region 322A of the first conductive layer 322 and a second area corresponding to the first dummy region 322D of the first conductive layer 322, and the first area and the second area are isolated by the first passivation layer 314. In an example illustrated in FIG. 3, one of the conductive through vias 370 may extend through the second active region 326A of the second conductive layer 326, the insulating layer 324, the first dummy region 322D of the first conductive layer 322, the first passivation layer 314, the first conductive plate 321, and the etch stop layer 312 to be electrically coupled to the conductive features 205A. Another conductive through via 370 may extend through the second dummy region 326D of the second conductive layer 326, the insulating layer 324, the first active region 322A of the first conductive layer 322, the first conductive plate 321, and the etch stop layer 312 to be electrically coupled to the conductive features 205A. In alternative embodiments, the first conductive plate 321 has an opening 321DO corresponding and overlapping the first dummy region 322D of first conductive layer, and the opening 321DO may be filled with the first passivation layer 314. In some embodiments, the conductive through vias 370 also extend into the conductive features 205A. In some embodiments, a plan view of the arrangement of the first conductive layer 322 and the first second conductive layer 326 are illustrated in FIG. 4E.

The second passivation structure 350 is formed over the first passivation structure 310, in accordance with some embodiments. The second passivation structure 350 may include a second passivation layer 352 formed over the filling layer 340, a third passivation layer 354 formed over the second passivation layer 352, and a dielectric layer 356 formed over the third passivation layer 354. In an embodiment, the second passivation layer 352 includes or is silicon nitride, silicon oxynitride, silicon carbide, silicon oxycarbonitride, a combination thereof, or the like. The third passivation layer 354 includes a material different from the second passivation layer 352, such as silicon oxide or glass, including silicate glass, borosilicate glass (BSG), phosphosilicate glass (PSG), borophosphosilicate glass (BPSG), a combination thereof, or the like. The dielectric layer 356 includes silicon oxide, silicate glass, a molding compound, or an organic material such as polybenzoxazoles (PBO), polyimide (PI), benzocyclobutene (BCB), other suitable organic polymers, or a combination thereof. The second passivation layer 352 and the third passivation layer 354 may be conformal layers. The dielectric layer 356 has a thickness greater than the second passivation layer 352 and the third passivation layer 354 and has a planar upper surface. In some embodiments, one of the second passivation layer 352 and the third passivation layer 354 may be omitted for saving cost.

In some embodiments, the conductive through vias 370 protrude from the first passivation structure 310 and extend into the second passivation structure 350, although the conductive through vias 370 may have a top surface level with the top surface of the second passivation layer 352. In embodiments that the conductive through vias 370 extend into the second passivation structure 350, the second passivation layer 352 and the third passivation layer 354 are conformally lying on the conductive through vias 370. In some embodiments, the protrusions of the conductive through vias 370 are conductive lines and serve as a redistribution layer (RDL).

In some embodiments, the bonding structures 360 are formed in or surrounded by the dielectric layer 356. The bonding structures 360 may further penetrate through the third passivation layer 354 and the second passivation layer 352 to be physically and/or electrically coupled to the conductive through vias 370. The bonding structures 360 may include Cu or other materials suitable for bonding (e.g., Ni, Au, Ag, Pd, Al, Sn). In some embodiments, the bonding structures 360 may also include barrier layer and/seed layer similar to the conductive through vias 370. Depending on the bonding requirements, the bonding structures 360 may be bumps that protrude over the dielectric layer 356 or have a top surface level with the top surface of the dielectric layer 356. In an embodiments, a bonding layer 358 may be additionally formed over the dielectric layer 356 for providing bonding functions, and the bonding structures 360 may protrude over or have a top surface level with the bonding layer 358. The bonding layer 358 may be a dielectric layer including such as silicon oxide

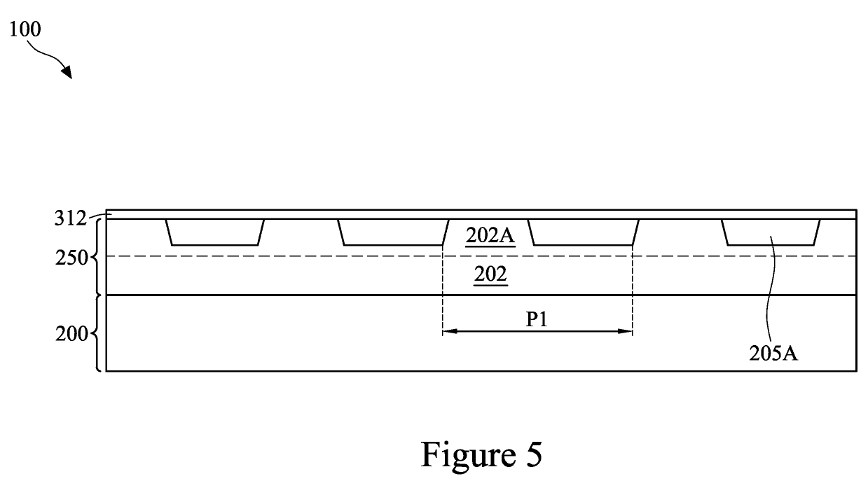

FIGS. 5-12 illustrate cross-sectional views at intermediate stages in the manufacturing the semiconductor device 100, in accordance with some embodiments. In FIG. 5, after the device layer 200 and the interconnect structure 250 are formed over the substrate 102, the etch stop layer 312 is formed over the top dielectric layer 202A and conductive features 205. The etch stop layer 312 may be formed by a suitable deposition process, such as CVD, ALD, PVD, PECVD, a combination thereof, or the like.

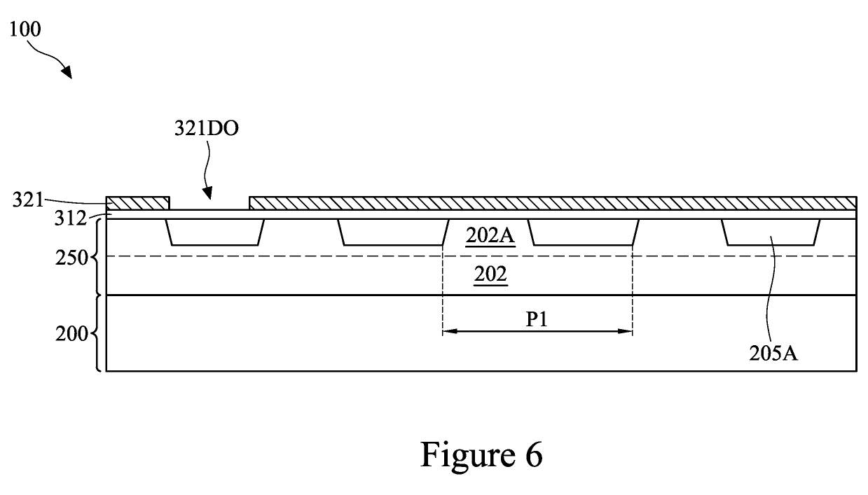

In FIG. 6, the first conductive plate 321 are formed over the etch stop layer 312. The first conductive plate 321 may be formed by depositing a layer and then patterned to include the opening 321DO. The deposition process may be a suitable deposition process, such as PVD or CVD. The patterning process may include forming a patterned mask over the as-deposited layer and then etching the layer to form the first conductive plate 321 that includes the opening 321DO. The etching may include a suitable etch process such as a dry etch or wet etch, and the patterned mask may be removed during or after the etching.

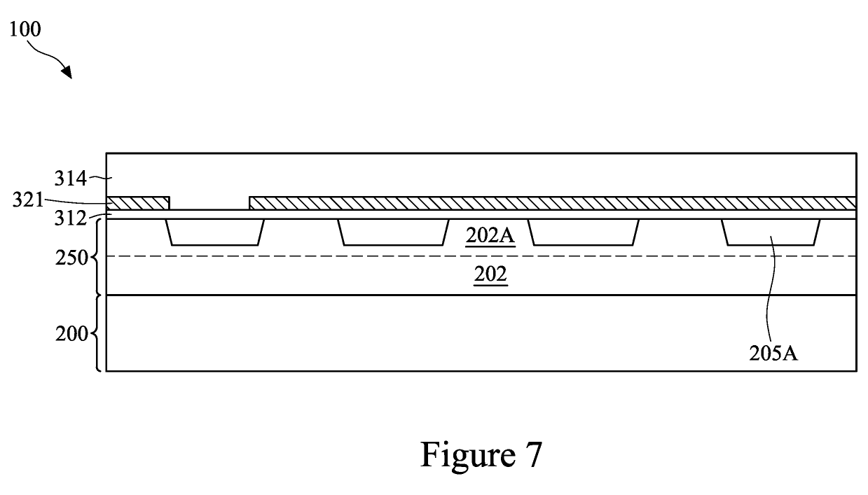

In FIG. 7, the first passivation layer 314 is formed over the first conductive plate 321 and the etch stop layer 312. The etch stop layer 312 may be formed by a suitable deposition process, such as CVD, ALD, PVD, PECVD, a combination thereof, or the like. The first passivation layer 314 may cover the first conductive plate 321, including covering upper surface and sidewall surfaces of the first conductive plate 321. In some embodiments, a planarization process, such as CMP or mechanical grinding, is performed to provide the first passivation layer 314 having a planarized upper surface.

In FIG. 8, an anisotropic etch process may be formed to form the trenches 318 in first passivation layer 314, in accordance with some embodiments. In an embodiment, a patterned mask is formed over the first passivation layer 314. The patterned mask may be a photoresist material, a hard mask (e.g., silicon oxide, TiN, TiO, or the like), or a combination thereof. An etch process may then be performed to transfer the pattern of the patterned mask to its underlying layers. The etch process may be an anisotropic etch process such as reactive ion etching (RIE) or neutral beam etching (NBE). For example, the etch process may include chemical including HBr, NF₃, O₂, SF₆, or combination thereof and physical ion bombardment. The etch process may be stopped by the first conductive plate 321 or the etch stop layer 312.

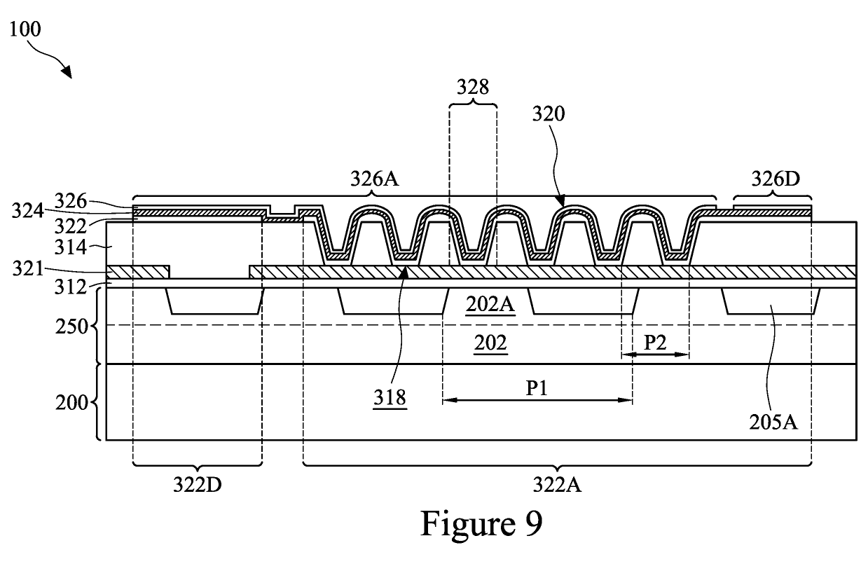

In FIG. 9, the first conductive layer 322, the insulating layer 324, and the second conductive layer 326 are formed in the trenches 318 and extend over the upper surface of the first passivation layer 314, in accordance with some embodiments. In detail, the material of the first conductive layer 322 is conformally formed in the trenches 318 over the upper surface of the first passivation layer 314. The material of the first conductive layer 322 may be formed by a suitable deposition process, such as PVD, CVD, or ALD. The material of the first conductive layer 322 may then be patterned to form the first active region 322A and the first dummy region 322D of the first conductive layer 322, such as by an anisotropic etch process including RIE or NBE.

The insulating layer 324 is conformally formed over the first conductive layer 322. In some embodiments, the insulating layer 324 is formed by CVD or ALD. Next, the second conductive layer 326 is conformally formed over the insulating layer 324. The second conductive layer 326 may be formed by PVD, CVD, or ALD. The material of the second conductive layer 326 may be is conformally formed in the trenches 318 and over the upper surface of the first passivation layer 314. The material of the second conductive layer 326 may be formed by a suitable deposition process, such as PVD, CVD, or ALD. The material of the second conductive layer 326 may then be patterned to form the second active region 326A and the second dummy region 326D, such as by an anisotropic etch process including RIE or NBE.

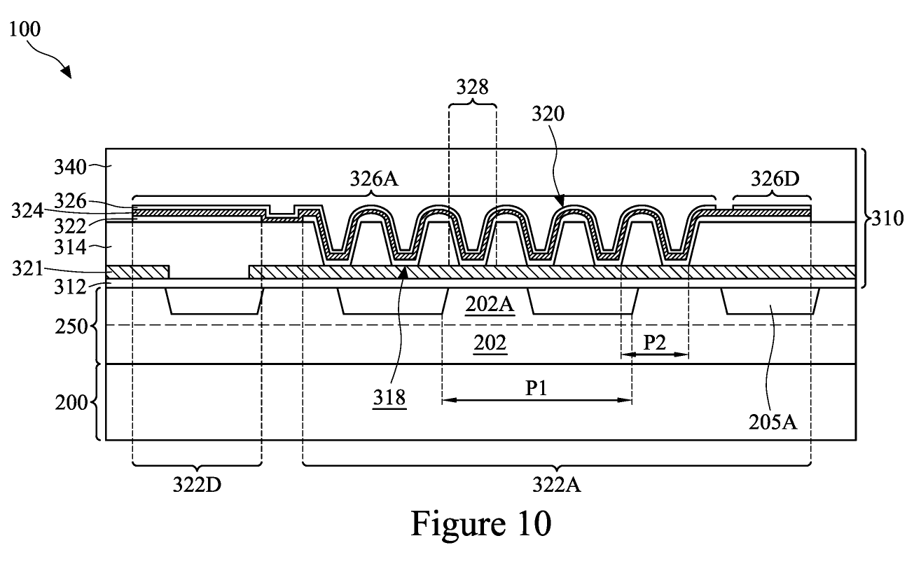

In FIG. 10, after the capacitor structure 320 is formed, a filling layer 340 is formed to cover the capacitor structure 320, in accordance with some embodiments. In embodiments that the trenches318 are not sealed, the filling layer 340 may extend into the trenches 318 to fill in the remaining space of the trenches 318. The filling layer 340 may be formed by a suitable deposition process, such as CVD, PECVD, LPCVD, or the like, and a planarization process such as chemical mechanic polish (CMP) or mechanical grinding may be performed to planarize the upper surface of the filling layer 340.

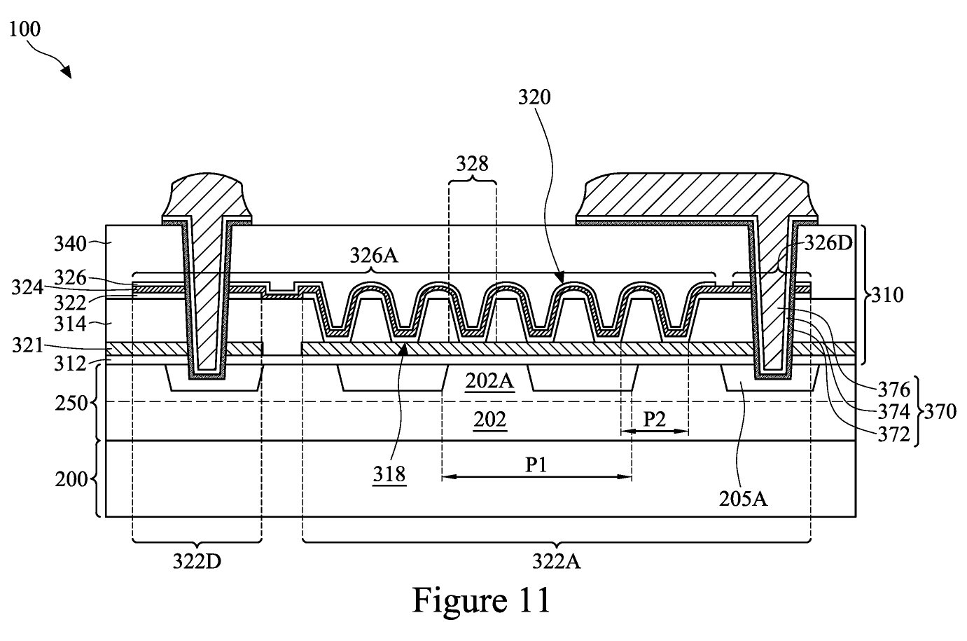

In FIG. 11, the conductive through vias 370 are formed in the etch stop layer 312, the first passivation layer 314, the capacitor structure 320, and the filling layer 340 and extend over the upper surface of the filling layer 340, in accordance with some embodiments. The conductive through vias 370 may be electrically coupled to the conductive features 205 of the interconnect structure. The conductive through vias 370 may be formed by one or more etch process and depositing layers in the openings. The etch processes may include an anisotropic process such as RIE or NBE. In some embodiments, a mask such as a hard mask layer may be disposed over the filling layer 340 prior to perform the etch process. The hard mask may include silicon oxide, titanium nitride, aluminum oxide, titanium oxide, or a combination thereof.

After the openings for the conductive through vias 370 are formed, the barrier layer 372, the seed layer 374, and the main conductive material 376 are formed in the openings subsequently. The barrier layer 372 and the seed layer 374 are be conformally deposited in the openings and over the upper surface of the filling layer 340, such as by ALD, CVD, or PVD. Next, a photoresist layer is formed over the barrier layer 372 or the seed layer 374 and patterned to expose the portions of the seed layer 374 in the openings and its adjacent portions. In some embodiments, a plating (e.g., electroplating or electroless plating) or other suitable deposition process is performed to formed the main conductive material 376 over the exposed portions of the seed layer 374. The as-deposited conductive through vias 370 may include protrusions over the upper surface of the filling layer 340. After the conductive through vias 370 are formed, the photoresist layer is removed by a suitable process, such as by a wet strip or an ash process, and the portions of seed layer 374 and barrier layer 372 are also removed by suitable wet etch processes. As illustrated in FIG. 3, the protrusions of conductive through vias 370 may remain and be covered by the second passivation structure 350. Alternatively, the protrusions of the conductive through vias 370 may be removed by a planarization process, such as CMP or mechanical grinding, depending on the design requirements of the bonding structures 360.

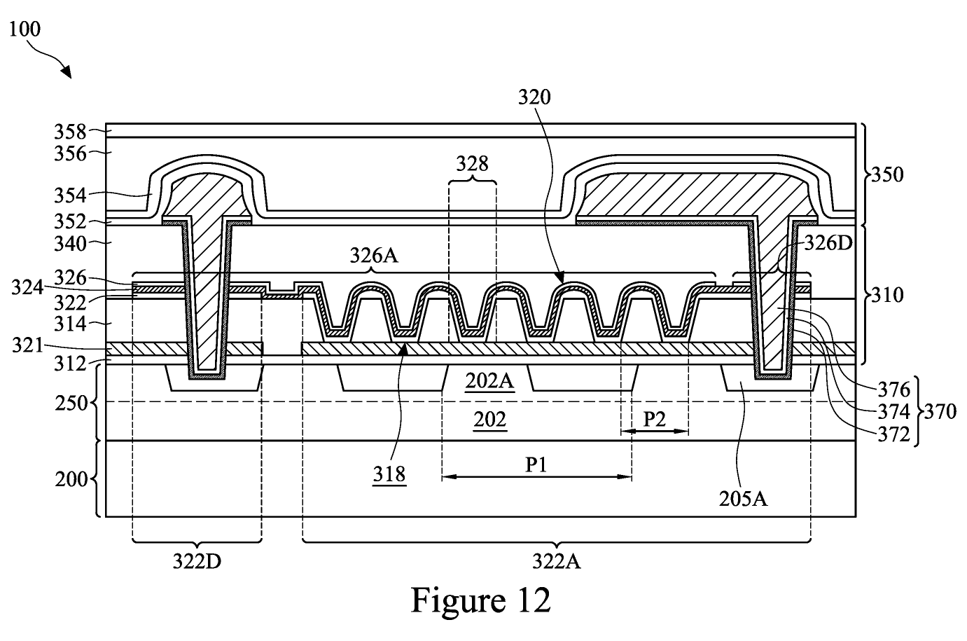

In FIG. 12, the second passivation structure 350 is formed over the first passivation structure 310 and the conductive through vias 370, in accordance with some embodiments. The formation of the second passivation structure 350 may include forming the second passivation layer 352 over the upper surfaces of the filling layer 340 and the conductive through vias 370 and forming the optional third passivation layer 354 over the second passivation layer 352. The second passivation layer 352 and the third passivation layer 354 may be conformally deposited, such as by CVD, PVD, ALD, or a combination thereof. Next, the dielectric layer 356 is formed over the second passivation layer 352 or the third passivation layer 354 (if exist). The dielectric layer 356 may be formed by suitable deposition processes, such as, CVD, PECVD, LPCVD, spin coating, a combination thereof, or the like. A planarization process such as CMP or mechanical grinding may be performed after the dielectric layer 356 are deposited. In some embodiments that the bonding layer 358 is needed, the bonding layer 358 is deposited over the upper surface of the dielectric layer 356, such as by CVD, PECVD, LPCVD, ALD, PVD, or the like.

Next, the bonding structures 360 are formed in the dielectric layer 356 (and the bonding layer 358, if exists), and a structure as illustrated in FIG. 3 is formed, in accordance with some embodiments. The formation of the bonding structures 360 may include forming openings extending the dielectric layer 356, the third passivation layer 354, and the second passivation layer 352 to expose the conductive through vias 370 by one or more etch processes and then disposing or depositing suitable conductive materials in the openings. In some embodiments, a planarization process is performed to planarize the bonding structures 360 to make the upper surface of the bonding structures 360 have an upper surface level with the upper surface of the dielectric layer 356 or the upper surface of the bonding layer 358, which may facilitate a direct bonding process.

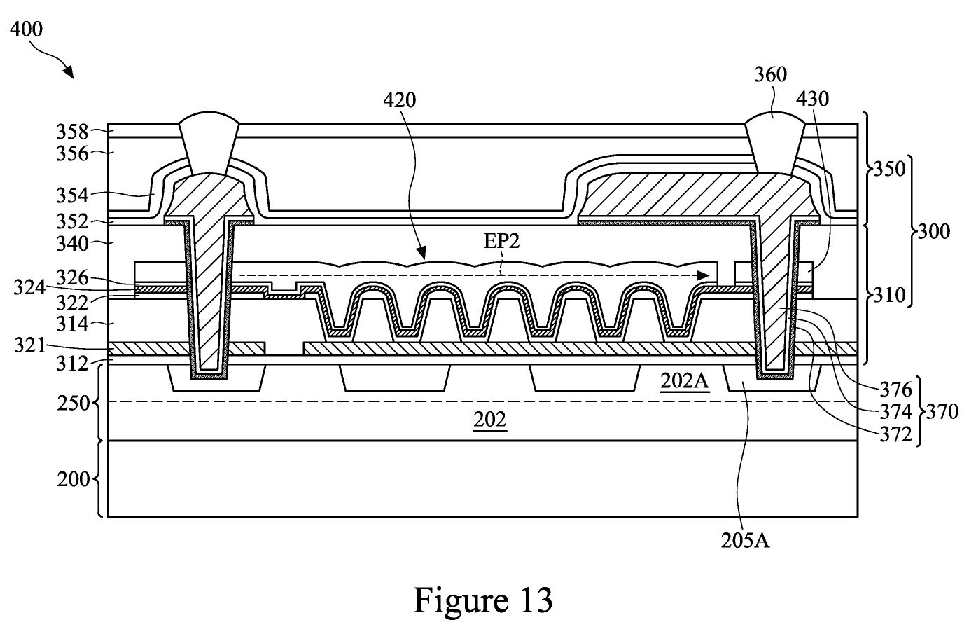

FIG. 13 illustrates a cross-sectional view of a semiconductor device 400, in accordance with some embodiments. The semiconductor device 400 is similar to the semiconductor device 100, and a second conductive plate 430 may be formed over the second conductive layer 326 to reduce the resistance.

In FIG. 13, the second conductive plate 430 may be formed over the second conductive layer 326. The second conductive plate 430 and the second conductive layer 326 may collectively work as the upper electrode of the capacitor structure 420. For example, the second conductive plate 430 may have a pattern corresponding to the second conductive layer 326. The second conductive plate 430 may have a bottom surface corresponding to the upper surface of the second conductive layer 326. In some embodiments that the trenches 318 are not sealed by the second conductive layer 326, the second conductive plate 430 may extend into the trenches 318. In an embodiment, the second conductive plate 430 has a thickness greater than the thickness of second conductive layer 426. In some embodiments, the second conductive plate 430 has a thickness greater than the thickness of the first conductive plate 321. For example, the second conductive plate 430 may have a thickness of about 25 nm to about 75 nm. The thicker the second conductive plate 430, the second conductive plate 430 can be more like a flat plate, thereby providing a shorter electrical path than that of the second conductive layer 326 (straight line EP2 in the second conductive plate 430 as compared to the folding electrical path of the second conductive layer 326). In some embodiments, the upper surface of the second conductive plate 430 is flatter than the upper surface of the second conductive layer 326. The second conductive plate 430 may have a material similar to the first conductive plate 321 and may be formed by methods similar to those of the first conductive plate 321. For example, the second conductive plate 430 may be or include a material that has a lower resistivity than that of the second conductive layer 326, although same material can also be implemented. With the formation of the second conductive plate 430, the capacitor structure 320 can have a reduced resistance and a wider filter bandwidth.

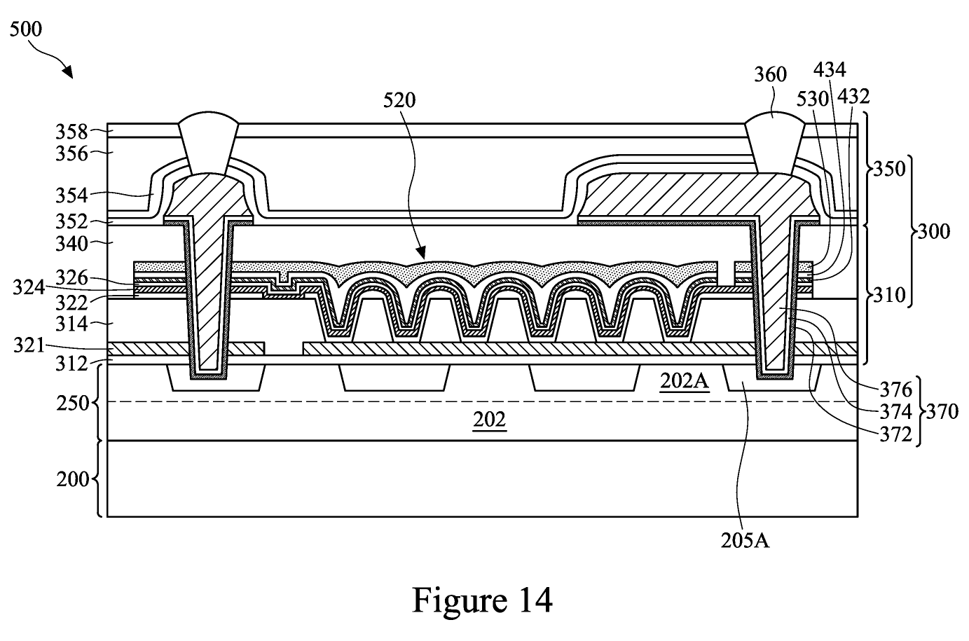

FIG. 14 illustrates a cross-sectional view of a semiconductor device 500, in accordance with some embodiments. The semiconductor device 500 is similar to the semiconductor device 100 or 300, and the capacitor structure 520 may have a metal-insulator-metal-insulator-metal (MIMIM) structure. In some embodiments, the insulating layer 432 may be or include the same material as the insulating layer 324 and may be formed by methods similar to those of the insulating layer 324. The third conductive layer 434 may be or include the same material as the second conductive layer 326 and may be formed by methods similar to those of the second conductive layer 326. The second conductive plate 530 may be or include the same material as the second conductive plate 430 and may be formed by methods similar to those of the second conductive plate 430.

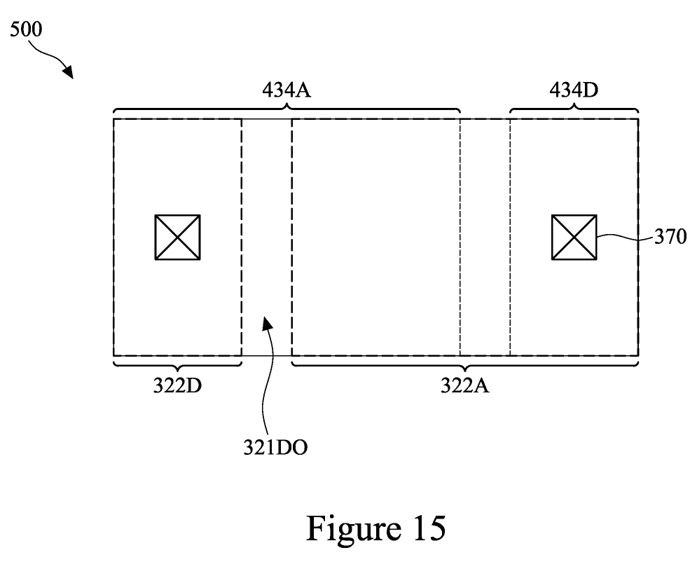

In an embodiment, because more layers, such as an insulating layer 432 and a third conductive layer 434, are formed in the trenches 318, the trenches 318 may be sealed by the third conductive layer 434. The second conductive plate 530 may not extend into the trenches 318 and have a reduced thickness, thereby being able to provide a substantial straight and shorter electrical path (comparing to the folded electrical path). For example, the second conductive plate 530 may have a thickness thinner than or equal to the thickness of the first conductive plate 321. The second conductive plate 530 may be greater than the thickness of the second conductive layer 326 and the third conductive layer 434. In some embodiments, a plan view of the arrangement of the first conductive layer 322 and the are illustrated in FIG. 15, where the third conductive layer 434 may have a second active region 434A and a third dummy region 434D corresponding to the second active region 326A and the second dummy region 326D, respectively. Although not illustrated in FIG. 15, the second conductive plate 530 may have a substantially same pattern as the third conductive layer 434 in the plan view.

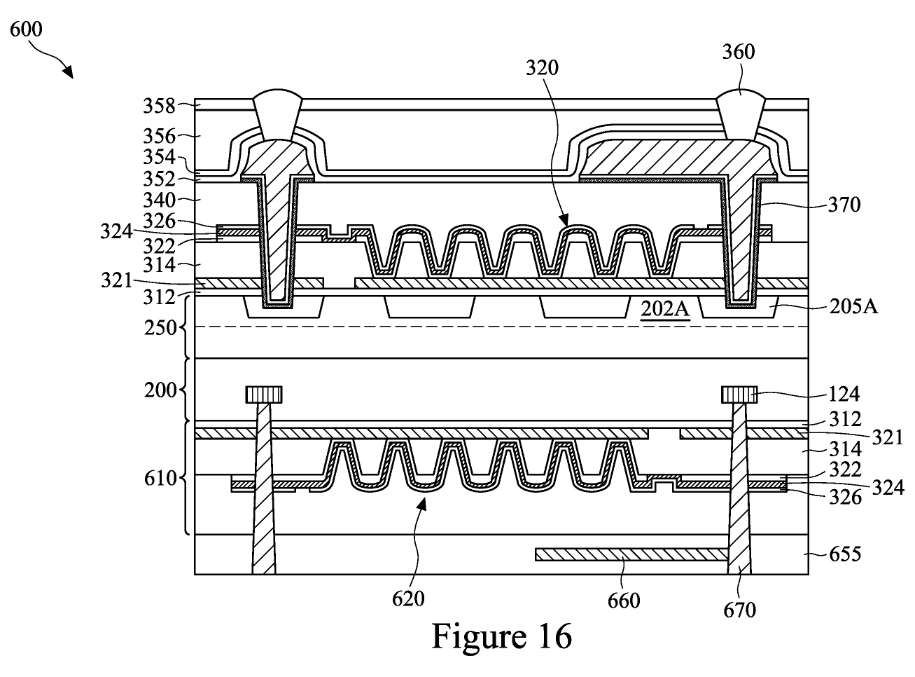

FIG. 16 illustrates a cross-sectional view of a semiconductor device 600, in accordance with some embodiments. The semiconductor device 600 may include a first passivation structure 610 and a capacitor structure 620 disposed over the backside of the device layer 200 (or the backside of the substrate 102). The capacitor structure 620 may be similar with the capacitor structure 320 and may be formed by methods similar to those of forming the capacitor structure 320. The first passivation structure 610 may be similar to the first passivation structure 310 and be formed by methods similar to those of forming the first passivation structure 610. For example, the first passivation structure 610 and the capacitor structure 620 may be vertically inverted as compared to the first passivation structure 610 and the capacitor structure 620, respectively.

A backside interconnect structure 655 may be disposed below the first passivation structure 610 and the capacitor structures 620 to provide power supply and/or additional signal connection to the device layer 200, in accordance with some embodiments. Conductive through vias 670 may penetrate through the backside interconnect structure 655, the capacitor structures 620, the first passivation structure 610 to be electrically coupled to the components in the device layer 200. The backside interconnect structure 655 may include conductive features disposed in dielectric layers, similar to the interconnect structure 250. The conductive through vias 670 extend through the first passivation structure 610 and physically and/or electrically coupled to the S/D regions 124 in the device layer 200. In an embodiment, the S/D regions are closer to the interconnect structure 250 than the first passivation structure 610. In addition, the backside interconnect structure 655, may be formed on the backside of the device layer 200 to provide power supply and/or additional signal connection to the device layer 200. The backside interconnect structure 655 may include power rails 660, which are conductive lines that electrically connect the S/D regions 124 in the device layer 200 to a reference voltage, a supply voltage, or the like.

By placing power rails on the backside of the semiconductor device 600 rather than on the front side of the semiconductor device 100, advantages may be achieved. For example, a gate density in the device layer 200 and/or an interconnect density in the interconnect structure 250 may be increased. Further, the backside of the semiconductor device 600 may accommodate wider power rails, reducing resistance and increasing the efficiency of power delivery to the semiconductor device 600. For example, a width of the power rails 660 may be at least twice a width of first level of conductive features 205 of the interconnect structure 250. Disposing the capacitor structures 620 at the backside of the device layer 200 also provides advantages. The capacitor structure 620 may be electrically coupled to the power rails 660 and/or the back through vias 670 that are physically and/or electrically coupled to source/drain regions 124 to regulate the large current provided from the conductive through vias 670 and/or power rails 660 before the large current transfers to the S/D regions 124, thereby protecting the devices (e.g., S/D regions 124) in the device layer 200 from being damaged by a large pulse. Although the capacitor structure 320 is used for the illustration in the semiconductor device 600, it is appreciated the capacitor structure 420 or 520 can also be used in the semiconductor device 600.

A semiconductor device including a capacitor structure is provided, in accordance with some embodiments. The capacitor structure includes trench-type capacitors. For example, the capacitor structure includes an insulating layer interposed a first conductive layer and a second conductive layer, and the insulating layer, the first conductive layer, and the second conductive layer are folded layers that extend into trenches to have an increased surface area. In some embodiments, the capacitor structure also includes a conductive plate connected to the first conductive layer and/or the second conductive layer. The conductive plate, along with the first or second conductive layer, work as an electrode of the capacitor structure. Because the conductive plate can provide a shorter electrical path than the first or second conductive layer, the conductive plate helps reduce sheet resistance of the electrode and enlarge filter bandwidth of the capacitor structure. Also, the capacitor structure may have increased charging and discharging speed. In some embodiments, the capacitor structure may also be disposed over a backside of the substrate opposite to the device layer. The backside capacitor structure may regulate large current and can protect the device layer from being damaged by a large pulse.

In an embodiment, a semiconductor device is provided. The semiconductor device includes an interconnect structure disposed over a substrate, wherein the interconnect structure includes conductive features disposed in a dielectric layer, and the conductive features have a first pitch in a first direction; an insulating layer disposed over the conductive features and the dielectric layer; a first conductive plate disposed over the insulating layer; a first passivation layer over the insulating layer and the first conductive plate, wherein the first passivation layer has a thickness different from a thickness of the dielectric layer; a plurality of trenches extending into the first passivation layer from an upper surface of the first passivation layer, wherein the trenches includes a first row along the first direction and a second row along the first direction, wherein the first row and the second row are neighbored in a second direction perpendicular to the first direction, wherein the trenches in the first row have a second pitch different from the first pitch; and a capacitor structure including a first conductive layer, a second insulating layer, and a second conductive layer, wherein the first conductive layer, the second insulating layer, and the second conductive layer are disposed over the upper surface of the first passivation layer and extend into the trenches, wherein the first conductive layer is in contact with the first conductive plate. In an embodiment, the first conductive layer has a first conductive material, and the first conductive plate has a second conductive material, wherein the second conductive material has a lower resistivity than the first conductive material. In an embodiment, the first conductive layer has a first thickness, and the first conductive plate has a second thickness greater than the first thickness. In an embodiment, the semiconductor further includes a second conductive plate over and in contact with the second conductive layer. In an embodiment, the second conductive layer includes a third thickness, and the second conductive plate has a fourth thickness greater than the third thickness. In an embodiment, a portion of the upper surface of the second conductive plate over the upper surface of the first passivation layer between the trenches is flatter than a portion of the upper surface of the second conductive layer over the upper surface of the first passivation layer between the trenches. In an embodiment, the semiconductor device further includes a conductive through via extending through the first conductive plate. In an embodiment, the trenches in the first row are misaligned with the trenches in the second row in the first direction.

In an embodiment, a semiconductor device is provided. The semiconductor device includes a device disposed over a first side of a substrate, wherein the device includes source/drain features, and each of the source/drain features includes a plurality of layers containing same semiconductor material with different concentrations; a first dielectric layer disposed over the device; conductive features disposed in the first dielectric layer; a second dielectric layer disposed over the conductive features and the first dielectric layer; a conductive plate disposed over the second dielectric layer; a first passivation layer disposed over the second dielectric layer, wherein the first passivation layer has a dielectric constant greater than a dielectric constant of the first dielectric layer; a plurality of trenches extending from an upper surface of the first passivation layer into the first passivation layer; and a first conductive layer, an insulating layer, and a second conductive layer are disposed over the upper surface of the first passivation layer and extending into the trenches, wherein the first conductive layer is in contact with the conductive plate, wherein the conductive plate has a thickness greater than a thickness of the first conductive layer. The semiconductor device of claim 9, wherein the first conductive layer includes a first active region and a first dummy region, and the second conductive layer includes a second active region and a second dummy region, wherein the first dummy region does not overlap the second dummy region in a plan view, wherein a portion of the first conductive layer in the trenches is in the first active region, and a portion of the second conductive layer in the trenches is in the second active region. In an embodiment, the first active region and the first dummy region of the first conductive layer are separated by the insulating layer. In an embodiment, the semiconductor device further includes a first conductive through via extending through the second dummy region of the second conductive layer, the first active region of the first conductive layer, and the second dielectric layer. In an embodiment, the first conductive through via extends through the conductive plate. In an embodiment, the semiconductor device further includes a second conductive through via extending through the second active region of the second conductive layer, the first dummy region of the first conductive layer, and the second dielectric layer, wherein the second conductive through via is separated from the conductive plate by the first passivation layer. In an embodiment, the semiconductor device further includes an insulating filling layer disposed over the second conductive layer and extending into the trenches; a passivation structure disposed over the insulating filling layer, wherein the first conductive through via further extends through the insulating filling layer and includes a protrusion extending in the passivation structure; and a bonding structure disposed in the passivation structure, wherein the bonding structure is exposed from the passivation structure and electrically coupled to the conductive through via. In an embodiment, the substrate includes a second side opposite to the first side of the substrate, wherein the source/drain features are disposed closer to the first side of the substrate than the second side of the substrate, wherein the semiconductor device further includes a conductive via extending from the second side of the substrate to be coupled to the source/drain features.

In an embodiment, a method for forming a semiconductor device is provided. The method includes forming an interconnect structure disposed over a substrate, wherein the interconnect structure includes conductive features disposed in a dielectric layer; forming a first insulating layer over the conductive features and the dielectric layer; forming a conductive plate over the first insulating layer; forming a passivation layer over the first insulating layer and the conductive plate, wherein the passivation layer has a thickness greater than a thickness of the first insulating layer, wherein the passivation layer has a dielectric constant greater than a dielectric constant of the dielectric layer; performing an etch process to from a plurality of trenches in the passivation layer, wherein the trenches expose the conductive plate; forming a first conductive layer over the passivation layer; forming a second insulating layer over the first conductive layer; and forming a second conductive layer over the first conductive layer, wherein the first conductive layer, the second insulating layer, and the second conductive layer extend into the trenches. In an embodiment, the forming the first conductive layer includes depositing a material and patterning the material before the forming the passivation layer. In an embodiment, the method further includes forming a conductive through via extending through the second conductive layer, the second insulating layer, the first conductive layer, the first passivation layer, and the first insulating layer. In an embodiment, the conductive through via further extends through the conductive plate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device, comprising:
an interconnect structure disposed over a substrate, wherein the interconnect structure comprises conductive features disposed in a dielectric layer, wherein the conductive features have a first pitch in a first direction;
an insulating layer disposed over the conductive features and the dielectric layer;
a first conductive plate disposed over the insulating layer;
a first passivation layer over the insulating layer and the first conductive plate, wherein the first passivation layer has a thickness different from a thickness of the dielectric layer;
a plurality of trenches extending into the first passivation layer from an upper surface of the first passivation layer, wherein the trenches includes a first row along the first direction and a second row along the first direction, wherein the first row and the second row are neighbored in a second direction perpendicular to the first direction, wherein the trenches in the first row have a second pitch different from the first pitch; and
a capacitor structure comprising a first conductive layer, a second insulating layer, and a second conductive layer, wherein the first conductive layer, the second insulating layer, and the second conductive layer are disposed over the upper surface of the first passivation layer and extend into the trenches, wherein the first conductive layer is in contact with the first conductive plate.

2. The semiconductor device of claim 1, wherein the first conductive layer has a first conductive material, and the first conductive plate has a second conductive material, wherein the second conductive material has a lower resistivity than the first conductive material.

3. The semiconductor device of claim 1, wherein the first conductive layer has a first thickness, and the first conductive plate has a second thickness greater than the first thickness.

4. The semiconductor device of claim 1, further comprising a second conductive plate over and in contact with the second conductive layer.

5. The semiconductor device of claim 4, wherein the second conductive layer comprises a third thickness, and the second conductive plate has a fourth thickness greater than the third thickness.

6. The semiconductor device of claim 5, wherein a portion of the upper surface of the second conductive plate over the upper surface of the first passivation layer between the trenches is flatter than a portion of the upper surface of the second conductive layer over the upper surface of the first passivation layer between the trenches.

7. The semiconductor device of claim 1, further comprising a conductive through via extending through the first conductive plate.

8. The semiconductor device of claim 1, wherein the trenches in the first row are misaligned with the trenches in the second row in the first direction.

9. A semiconductor device, comprising:
a device disposed over a first side of a substrate, wherein the device comprises source/drain features, wherein each of the source/drain features comprises a plurality of layers containing same semiconductor material with different concentrations;
a first dielectric layer disposed over the device;
conductive features disposed in the first dielectric layer;
a second dielectric layer disposed over the conductive features and the first dielectric layer;
a conductive plate disposed over the second dielectric layer;
a first passivation layer disposed over the second dielectric layer, wherein the first passivation layer has a dielectric constant greater than a dielectric constant of the first dielectric layer;
a plurality of trenches extending from an upper surface of the first passivation layer into the first passivation layer; and
a first conductive layer, an insulating layer, and a second conductive layer are disposed over the upper surface of the first passivation layer and extending into the trenches, wherein the first conductive layer is in contact with the conductive plate, wherein the conductive plate has a thickness greater than a thickness of the first conductive layer.

10. The semiconductor device of claim 9, wherein the first conductive layer comprises a first active region and a first dummy region, and the second conductive layer comprises a second active region and a second dummy region, wherein the first dummy region does not overlap the second dummy region in a plan view, wherein a portion of the first conductive layer in the trenches is in the first active region, and a portion of the second conductive layer in the trenches is in the second active region.

11. The semiconductor device of claim 10, wherein the first active region and the first dummy region of the first conductive layer are separated by the insulating layer.

12. The semiconductor device of claim 10, further comprising a first conductive through via extending through the second dummy region of the second conductive layer, the first active region of the first conductive layer, and the second dielectric layer.

13. The semiconductor device of claim 12, wherein the first conductive through via extends through the conductive plate.

14. The semiconductor device of claim 10, further comprising a second conductive through via extending through the second active region of the second conductive layer, the first dummy region of the first conductive layer, and the second dielectric layer, wherein the second conductive through via is separated from the conductive plate by the first passivation layer.

15. The semiconductor device of claim 12, further comprising:
an insulating filling layer disposed over the second conductive layer and extending into the trenches;
a passivation structure disposed over the insulating filling layer, wherein the first conductive through via further extends through the insulating filling layer and comprises a protrusion extending in the passivation structure; and
a bonding structure disposed in the passivation structure, wherein the bonding structure is exposed from the passivation structure and electrically coupled to the conductive through via.

16. The semiconductor device of claim 9, wherein the substrate comprises a second side opposite to the first side of the substrate, wherein the source/drain features are disposed closer to the first side of the substrate than the second side of the substrate, wherein the semiconductor device further comprises a conductive via extending from the second side of the substrate to be coupled to the source/drain features.

17. A method for forming a semiconductor device, comprising:
forming an interconnect structure disposed over a substrate, wherein the interconnect structure comprises conductive features disposed in a dielectric layer;
forming a first insulating layer over the conductive features and the dielectric layer;
forming a conductive plate over the first insulating layer;
forming a passivation layer over the first insulating layer and the conductive plate, wherein the passivation layer has a thickness greater than a thickness of the first insulating layer, wherein the passivation layer has a dielectric constant greater than a dielectric constant of the dielectric layer;
performing an etch process to from a plurality of trenches in the passivation layer, wherein the trenches expose the conductive plate;
forming a first conductive layer over the passivation layer;
forming a second insulating layer over the first conductive layer; and
forming a second conductive layer over the first conductive layer, wherein the first conductive layer, the second insulating layer, and the second conductive layer extend into the trenches.

18. The method of claim 17, wherein the forming the first conductive layer comprises depositing a material and patterning the material before the forming the passivation layer.

19. The method of claim 17, further comprising forming a conductive through via extending through the second conductive layer, the second insulating layer, the first conductive layer, the passivation layer, and the first insulating layer.

20. The method of claim 19, wherein the conductive through via further extends through the conductive plate.
